(19) United States
(12) Patent Application Publication
(10) Pub. No.: US 2011/0163767 A1
(43) Pub. Date: Jul. 7, 2011

(54) OCCUPANT DETECTION SYSTEM AND METHOD

(76) Inventors: Yin-Yu Chen, Kokomo, IN (US); Morgan D. Murphy, Kokomo, IN (US); Charles A. Gray, Noblesville, IN (US); Duane D. Fortune, Lebanon, IN (US)

(21) Appl. No.: 12/683,530

(22) Filed: Jan. 7, 2010

(51) Int. Cl. G01R 27/26

(52) U.S. Cl. 324/679

(57) ABSTRACT

An occupant detection system and method are provided. The system includes a capacitive sensor having an electrode arranged in a seat proximate to an expected location of an occupant for sensing an occupant presence approximate thereto. The capacitive sensor is configured to provide an output indicative of the sensed occupant presence. The system also includes a force sensor arranged within the seat providing an output indicative of a sensed force applied to the seat. The system further includes occupant detection circuitry for processing the capacitive sensor output and force sensor output and detecting a state of occupancy of the seat based on the capacitive sensor output and the force sensor output.

### TECHNICAL FIELD

The present invention generally relates to occupant sensing systems, and more particularly relates to a system and method for detecting an occupant on a vehicle seat that includes an electrode configured to have a resonate frequency that is dependent on presence of an occupant.

### BACKGROUND OF THE INVENTION

Automotive vehicles are commonly equipped with air bags and other devices that are selectively enabled or disabled based upon a determination of the presence of an occupant in a vehicle seat. It has been proposed to place electrically conductive material in a vehicle seat to serve as an electrode for detecting the presence of an occupant in the seat. For example, U.S. Patent Application Publication No. 2009/0267622 A1, which is hereby incorporated herein by reference, describes an occupant detector for a vehicle seat assembly that includes an occupant sensing circuit that measures the impedance of an electric field generated by applying an electric signal to the electrode in the seat. The presence of an occupant affects the electric field impedance about the electrode that is measured by the occupant sensing circuit.

While the aforementioned technique generally detects presence of an occupant, situations may exist in which the system may not categorize an occupant. For example, irregularities caused by liquid present on the seat or electronic fields that disrupt the field readings, such as a laptop computer placed on the seat, can cause irregularities in the sensed signal. What is needed is a system and method that can determine the presence of an occupant in a vehicle seat having an electrode which prevents misclassification of occupancy due to such signal irregularities.

### SUMMARY OF THE INVENTION

According to one aspect of the present invention, an occupant detection system is provided. The system includes an electrode arranged proximate to an expected location of an occupant for sensing an occupant presence proximate thereto. The electrode is configured to provide an electrode impedance indicative of a sensed occupant presence. The system also includes a force sensor arranged within a seat and providing an output indicative of a threshold force applied to the seat. The system further includes occupant detection circuitry for processing the electrode impedance from the electrode in the output of the force sensor and detecting a state of occupancy of the seat based on the electrode and the force sensor output.

According to another aspect of the present invention, a method of detecting an occupant in a seat is provided. The method includes the steps of applying an alternating current signal to an electrode arranged in a seat proximate to an expected location of an occupant for generating an electric field at the expected location, detecting a voltage response to an electric field, and generating a first output based on voltage response indicative of a characteristic of an occupant. The method also includes the steps of sensing force applied to the seat by an occupant with the use of a force sensor located in the seat, and generating a second output indicative of the sensed force on the seat. The method further includes the step of processing the first output and the second output to detect a state of occupancy of a seat based on the first output and the second output.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a perspective partial exploded view of a seat assembly incorporating an occupant detection system, according to one embodiment;

FIG. 2 is an enlarged exploded view of the weight based force sensor employed in the occupant detection system, according to one embodiment;

FIG. 3 is a block/circuit diagram of the occupant detection system, according to one embodiment;

FIGS. 4A and 4B is a flow diagram illustrating a routine for sensing occupancy based on capacitive sensing;

FIG. 5 is a flow diagram for classifying an occupant based on the capacitor sensing;

FIG. 6 is a flow diagram illustrating a routine for sensing occupancy based on weight based sensing; and

FIG. 7 is a flow diagram illustrating a routine for determining occupant classification, according to one embodiment.

### DESCRIPTION OF THE PREFERRED EMBODIMENTS

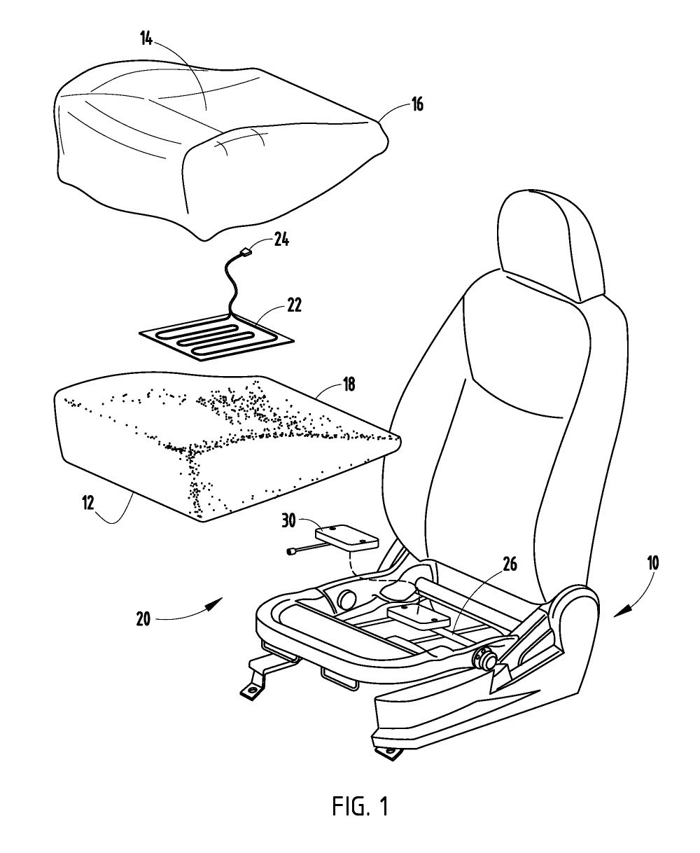

Referring now to FIG. 1, an exemplary automotive vehicle seat assembly 10 is generally shown having a top side seating surface 14 suitable for supporting an occupant (not shown). The seat assembly 10 is adapted to be installed in a vehicle passenger compartment, such as a car seat, according to one embodiment, but could be used in any kind of vehicle, such as an airplane, according to another embodiment. The seat assembly 10 has a foam cushion 18 and an outer covering 16, and a capacitive sensing electrode 22 installed in the seat assembly 10 on or proximate to the top side seating surface 14. In the embodiment shown, the electrode 22 may be installed on top of the foam cushion 18 and below the outer covering 16 (referred to as the A-surface). The electrode 22 effectively serves as an antenna or capacitive sensor to detect occupancy of the seat 10. The electrode 22 may be formed of suitable materials that allow for electrical conductivity for the electrode 22 to receive a signal and generate a voltage output that may include metal wire, conductive fiber, metal foil, metal ribbon, conductive ink and other conductive materials formed in the shape of a mat or other shape. The vehicle seat assembly 10 includes an occupant detection system 20 which utilizes the capacitive based electrode 22 and a weight based force sensor 30 for sensing occupancy of the seat assembly 10.

The weight based force sensor 30 is shown located below the top side seating surface 14 in a lower hidden surface 12 (referred to as the B-surface) below the foam cushion 18 and its covering 16. In one embodiment, the force sensor 30 may be configured as a seatbelt reminder (SBR) sensor installed on a frame 26 or on a spring supporting the seat cushion. The force sensor 30 senses force or weight applied to the top surface of the seat assembly 14 and provides an output signal indicative of the sensed force. The occupant detection system 20 advantageously employs the sensed force output and the capacitive sensing output to provide a determination of sensed occupancy of the seat assembly 10.

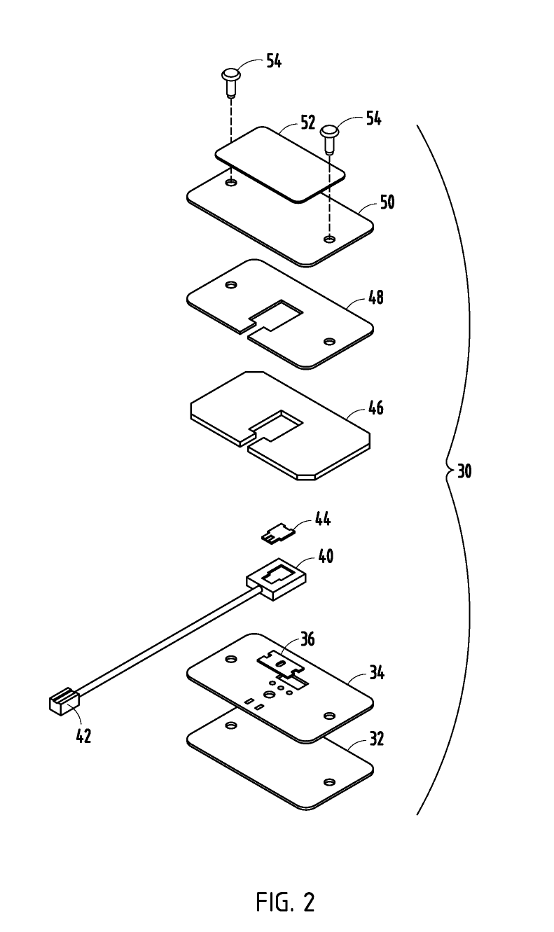

The weight based force sensor 30 is illustrated in FIG. 2 as a seatbelt reminder sensor, according to one embodiment. The force sensor 30 generally includes a bottom felt pad 32 which may rest on top of the seat frame 26 or a spring-like structure at the B-surface of the seat assembly 10. The felt pad 32 prevents squeaks and rattles. A backer board 34 is disposed on top of the felt pad 32 and serves to create a uniform reaction surface. A printed circuit board adhesive 36 is provided on top of the backer board 34. A circuit board 40 is provided in conjunction with a metal dome switch 44 that serves as a switch circuit assembly to provide force sensing due to weight applied to the top surface 14 of the seat assembly 10. The circuit board 40 is connected to a connector assembly 42 which may be connected to an electronic control unit (ECU). An elastomer spring 46 is disposed around the dome switch 44 and printed circuit board 40. The elastomer spring 46 may be a silicone mat and is compressible to transfer predetermined forces applied to the seat top surface 14 prior to contact with the dome switch 44. It should be appreciated that the dome switch 44 may include a switch actuator built therein or disposed on top thereof which causes actuation of the switch 44 upon application of sufficient force. Disposed on top of the elastomer spring 46 is an optimal spacer 48 for tuning and a topper board 50 that distributes applied forces. The switch actuator may be located on the bottom surface of the topper board 50. An adhesive 52 is applied on top of the topper board 50 such that the switch may be adhered to the bottom surface of the foam seat. Pushpins 54 may be assembled within openings to hold the force sensor assembly components together. While a seatbelt reminder sensor is shown and described herein as a force sensor according to one embodiment. It should be appreciated that other force sensors, such as a fluid bladder-type sensor may be employed to provide a sensed force on the seat assembly 10, according to other embodiments.

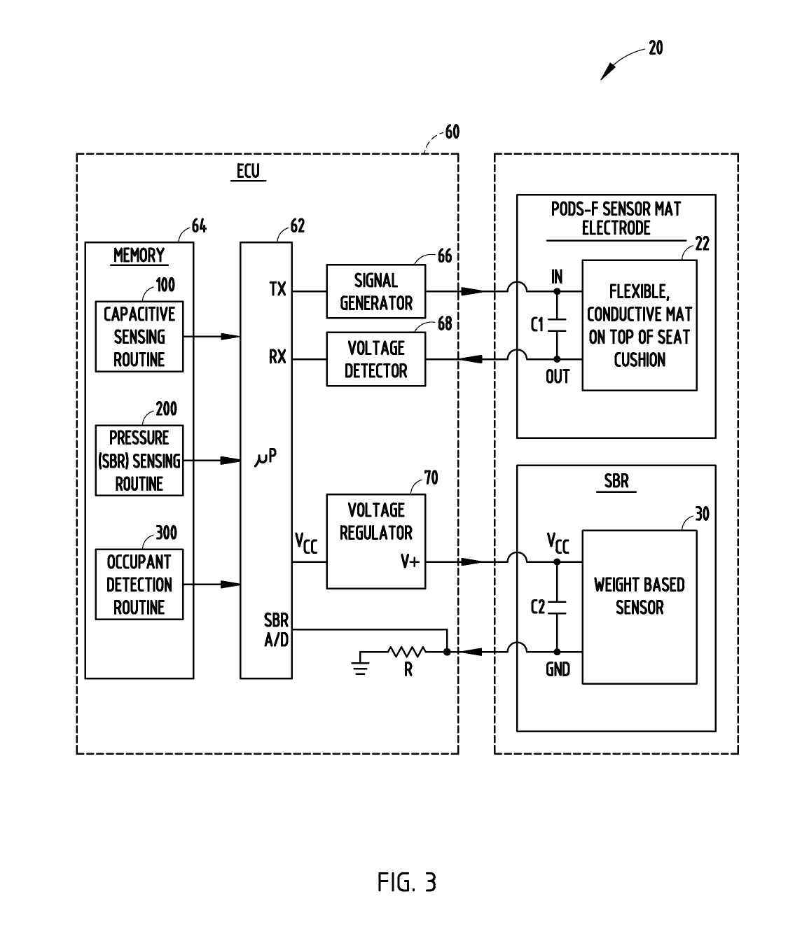

The occupant detection system 20 is illustrated in FIG. 3, according to one embodiment. The occupant detection system 20 includes occupant detection circuitry shown implemented as an electronic control unit (ECU) 60 in communication with both the capacitive based electrode 22 and the weight based force sensor 30. The ECU 60 is shown including a microprocessor 62 and memory 64. Memory 64 includes a capacitive sensing routine 100, a force sensing routine 200 and an occupant detection routine 300 that utilizes outputs generated by both the capacitive and force sensing routines. The routines 100, 200 and 300 may be executed by the microprocessor 62. It should be appreciated that other control circuitry may be employed to process the various routines and provide outputs as described herein.

The ECU 60 is also shown having a signal generator 66 and a voltage detector 68. The signal generator 66 is configured to output a plurality of alternating current (AC) signals at different frequencies. This may include generating a first sine wave signal at a first frequency during a first time period and a second sine wave signal at a second frequency during a second time period. A total of n AC signals at n frequencies may be generated. The plurality of n signals may be output simultaneously or sequentially by the signal generator 66 and applied to the electrode 22 to generate an electric field proximate to the top side seat surface 14.

The signal generator 66 is configured to generate an electric field projected to a location at which an object (occupant) is to be detected, such as the top side seating surface 14 of the seat assembly 10. The impedance of a load affects the voltage response received by the voltage detector 68. The voltage detector 68 measures a voltage for each of the n frequencies at the n time periods. The measured voltages may depend upon the impedance of the load which may include impedance caused by an occupant and environmental conditions such as humidity, moisture and temperature.

It should be appreciated that the microprocessor 62 may include a plurality of noise filters (not shown) and may convert the measured voltages into digital voltage amplitudes. The voltage amplitudes may be compared to determine if a change in voltage has occurred amongst the plurality of frequencies. A change or difference in voltages may be indicative of the presence of an environmental condition that will affect the impedance of a load.

The occupant detection system 20 also detects sensed force signals from the force sensor 30 shown as the seatbelt reminder sensor in one embodiment. The occupant detection system 20 advantageously processes the capacitive based sensor output and the weight based force sensor output and determines occupancy of the vehicle seat. The output of the occupant detection system 20 may be used to enable, disable or change the response of a vehicle air bag system or other vehicle systems. In some applications, deployment of an air bag may be enabled when a person or object of a specific size or shape is seated in the vehicle. The size of a person may be proportional to the person's impedance and will affect the voltage sensed by the electrode 22. Additionally, the weight of the person will affect the output of the force sensor 30. Additionally, environmental conditions may affect the loading on the system, particularly the electrode 22. The electrode 22 may be compensated to actively control the deployment system by compensating for the detected environmental conditions.

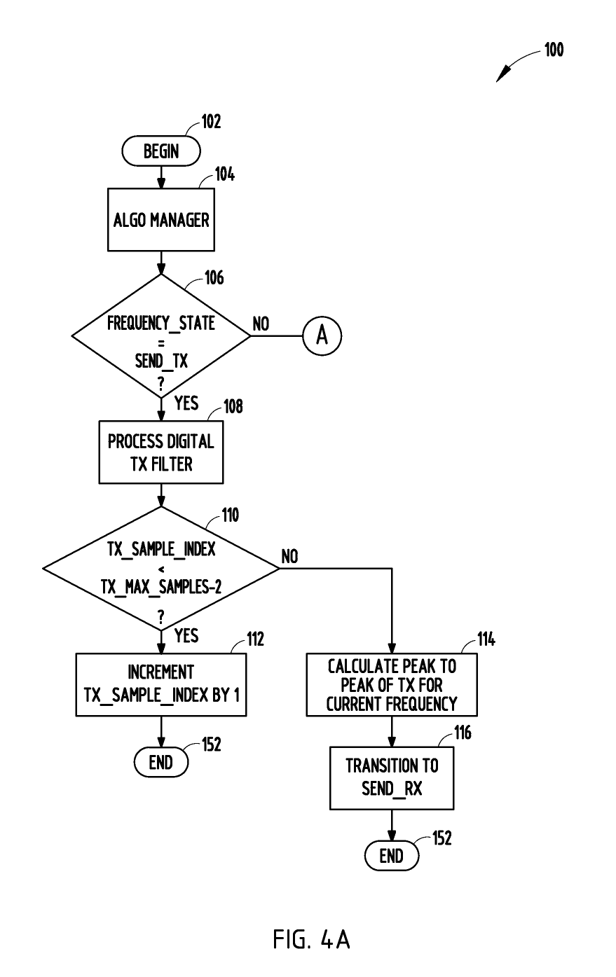

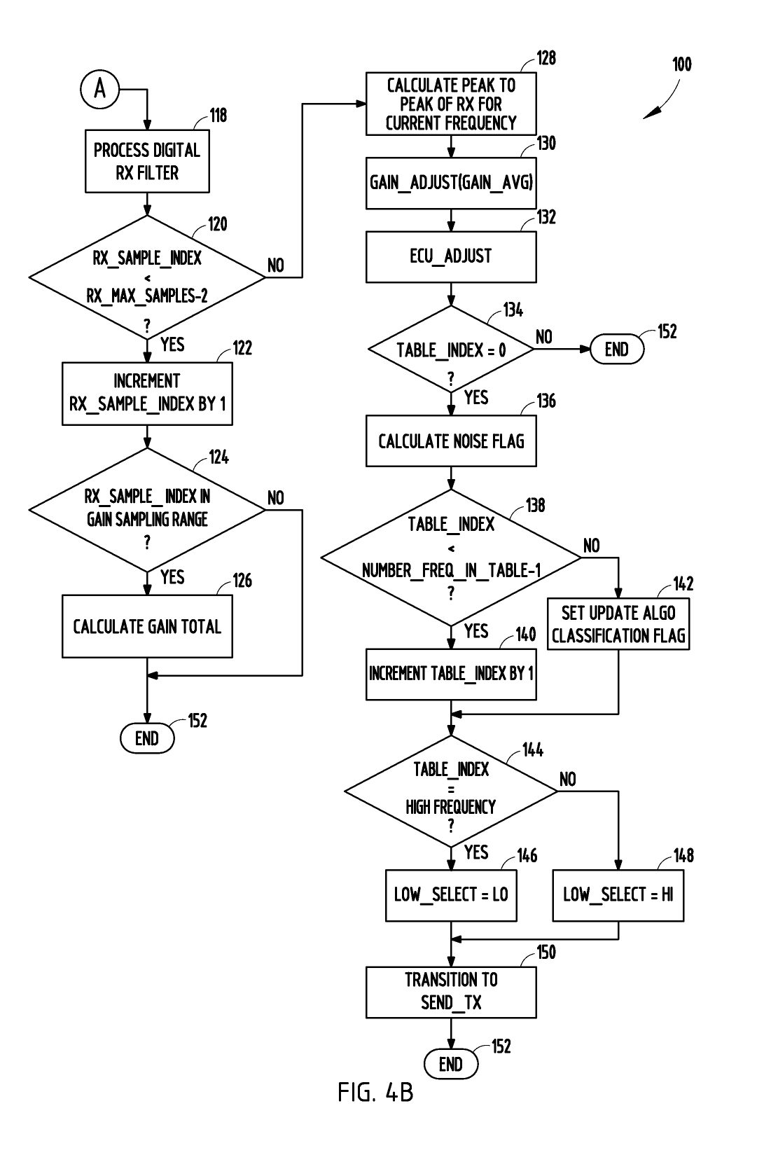

Referring to FIGS. 4A and 4B, a capacitive sensing routine 100 is illustrated according to one embodiment. Routine 100 begins at step 102 and proceeds to step 104 to call the algorithm manager, which may occur at a rate of 120 microseconds, according to one example. Next, at decision step 106, routine 100 determines if the frequency state is set equal to the send TX signal such that the AC transmit signal is being transmitted and, if so, processes the digital transmit filter at step 108. At decision step 110, routine 100 determines if the transmit sample index is less than the maximum transmit samples minus two, such that the requisite number of four frequency signals have completed their transmission. If the transmission of four frequency signals is not complete, routine 100 proceeds to increment the TX_Sample index by one in step 112 and ends at step 152. If the transmit signals are done transmitting at the requisite four frequencies, routine 100 proceeds to step 114 to calculate the peak-to-peak amplitude of the transmit signal for the current frequency to get a measurement of the amplitude, and then proceeds to step 116 to transition to the send RX receive signal. Accordingly, routine 100 transmits signals at four separate frequencies. According to one embodiment, three of the frequencies are high frequencies generally in a range near about 140 millihertz, and the one low frequency signal is generally in a range near about 2 millihertz.

Returning back to step 106, if routine 100 determines that the frequency state is not in the transmit mode, routine 100 proceeds to step 118 to process the digital received RX filter. According to one embodiment, the RX filter uses a 1481 tap filter for the low frequency, and a 121 tap filter for the high frequencies. Next, routine 100 proceeds to decision step 120 to determine if the received RX sample_index is less than the received sample maximum minus two so as to determine whether or not RX signals have been received at all four frequencies. If the RX signals have not been received at all four frequencies, routine 100 proceeds to step 122 to increment the RX sample_index by one, and then determines in decision step 124 if the RX sample_index is within the gain sampling range and, if so, calculates a gain total at step 126. Otherwise, routine 100 ends at step 122. If the received signal has been received for all four frequencies, routine 100 proceeds to step 128 to calculate the peak-to-peak amplitude of the received RX signal for the current frequency. Next, at step 130, routine 100 performs a gain adjust to adjust the gain of the amplifier in the waveform generator to keep the average signal amplitude substantially constant. This may be achieved with a feedback loop to compensate for environmental effects, such as humidity. At step 132, routine 100 adjusts the ECU to calculate the Q_{X} raw value, which normalizes for variations in the ECU synthesizer chip, such that the output remains substantially stable. At decision step 134, routine 100 determines if the table index is equal to zero and, if not, ends at step 152. If the table index is set equal to zero, routine 100 proceeds to step 136 to calculate a noise flag and then proceeds to decision step 138 to determine if the table_index is less than the number of frequencies in the table minus one, which essentially checks for noise on each individual frequency signal. If the decision in step 138 is determined to be yes, routine 100 proceeds to step 140 to increment the table_index by one. Otherwise, the update algorithm classification flag is set at step 142. At decision step 144, routine 100 determines if the table_index is equal to the high frequency and, if so, sets the low select to low at step 146 before transitioning to the send TX signal at step 150 and ending at 152. Otherwise, the low select signal is set to high at step 148 before transitioning to the send TX signal at step 150.

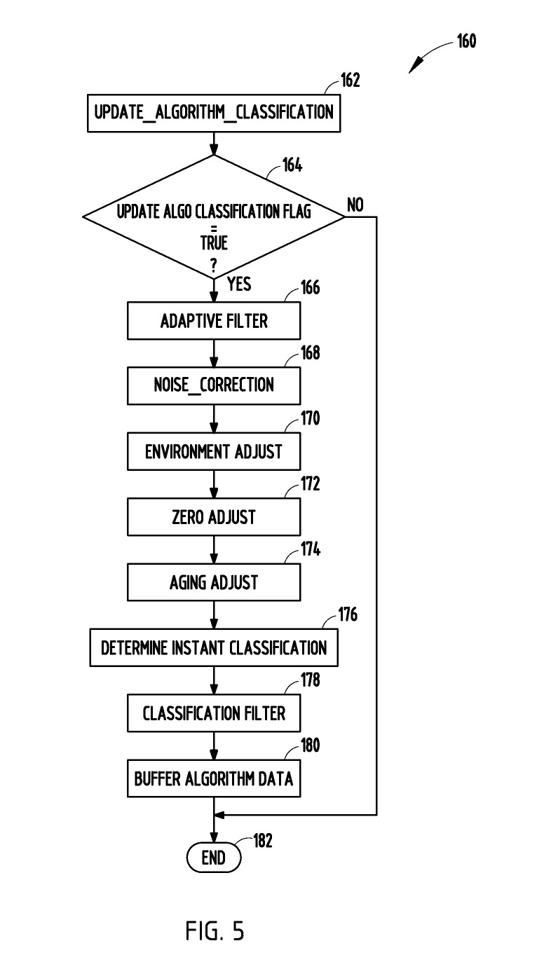

Referring to FIG. 5, an update algorithm classification routine for classifying the capacitive sensed occupant is illustrated as generally indicated by identifier 160. Routine 160 begins the update algorithm classification at step 162, and proceeds to decision step 164 to determine whether the update algorithm classification flag is set equal to true (e.g., binary 1), and if not, ends at step 182. If the update algorithm classification flag is set equal to true, then routine 160 proceeds to step 166 to perform adaptive filtering and then to step 168 to provide noise correction. Next, routine 160 proceeds to the environmental adjust step 170 to compensate for environmental conditions, such as humidity. Next, a zero adjusts step is performed at step 172 in which the capacitive value for an empty seat may be adjusted so as to normalize the seat setting, which may occur at the vehicle assembly facility, according to the automotive application. At step 174, routine 160 may periodically provide an aging adjust step to adjust for variations in values during aging of the seat. At step 176, routine 160 may determine an instant classification which may be achieved by comparing the median Q_{X} value against a threshold value. At step 178, routine 160 may perform a classification filter which may look for a plurality of comparisons to obtain consecutive Q_{X} middle values exceeding a threshold value. It should be appreciated that Q_{X} is the approximate measure of capacitance and that four Q_{X} values may be obtained, corresponding to the three high frequencies and the fourth low frequency. The middle peak-to-peak amplitude value of the three high frequency Q_{X} values may be used to determine whether or not to classify an occupant as an adult. The difference between the low and the high Q_{X} values may be used to adjust for humidity. Q_{X} may be defined in one embodiment by the following equation:

$${Q}_{X} = \frac{{R}_{X} - {T}_{X}}{{T}_{X}} . sensed capacitor value ,$$

wherein Q_{X} is the count per picofarad. At step 180, routine 160 may perform a buffer algorithm to buffer the data, before ending at step 182. Accordingly, it should be appreciated that the routines 100 and 160 advantageously provide for an output signal indicative of an occupant and the classification of the occupant based on the capacitive sensor. The output of the capacitive sensor may then be used in the occupant detection sensing routine described herein.

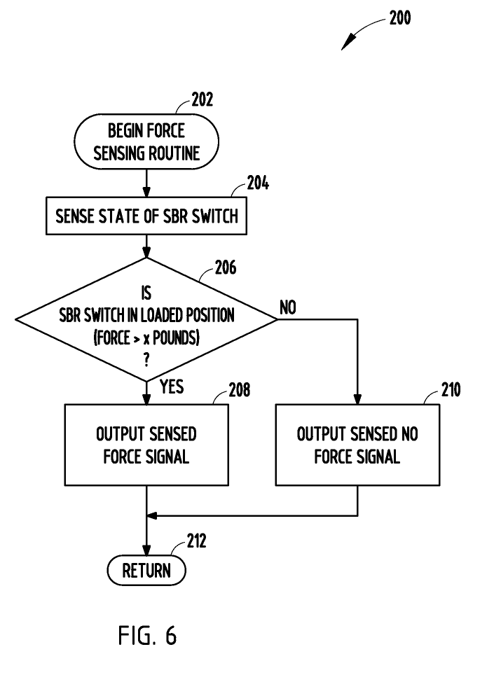

Referring to FIG. 6, a force sensing routine 200 is illustrated according to one embodiment. Routine 200 begins at step 202 and proceeds to step 204 to sense the state of the seatbelt reminder (SBR) switch which provides an indication as to the amount of force sensed in a seat exceeding a minimum threshold. Next, routine 200 proceeds to decision step 206 to determine if the SBR switch is in a loaded position, such that the sensed amount of force is greater than X pounds, where X may be set equal to twenty-seven (27) pounds, according to one example. If the SBR switch is in the loaded position, indicative of sensing a minimal amount of force indicative of a potential occupant, routine 200 proceeds to step 208 to output a sensed force signal before returning at step 212. If the SBR switch is not in the loaded position such that the amount of the force in the seat is less than X pounds, then routine 200 outputs the sensed no force signal at step 210, before returning at step 212. Accordingly, routine 200 advantageously provides a force sensor output indicative of whether the seat has a minimal amount of force loaded thereon. The force sensor output may then be used in the occupant detection system as described herein.

In the embodiment shown in FIG. 6, the force sensor may be configured such that the dome switch as a two-state switch having two states, namely for empty seat and loaded seat states which allows for classification of no occupant or an occupant, respectively. However, it should be appreciated that the force sensor may detect more than two states of the seat load. According to another embodiment, the force sensor may employ a three-state switch for detecting an empty seat, a low load seat, and a high load seat, respectively, indicative of three classification states, namely, empty seat, child in seat, and adult in seat. In this embodiment, routine 200 may include two threshold settings, one indicative of a child force and the other indicative of an adult force such that classification of a child or an adult can be determined. It should be appreciated that more than three states of the sensor may be employed according to further embodiments.

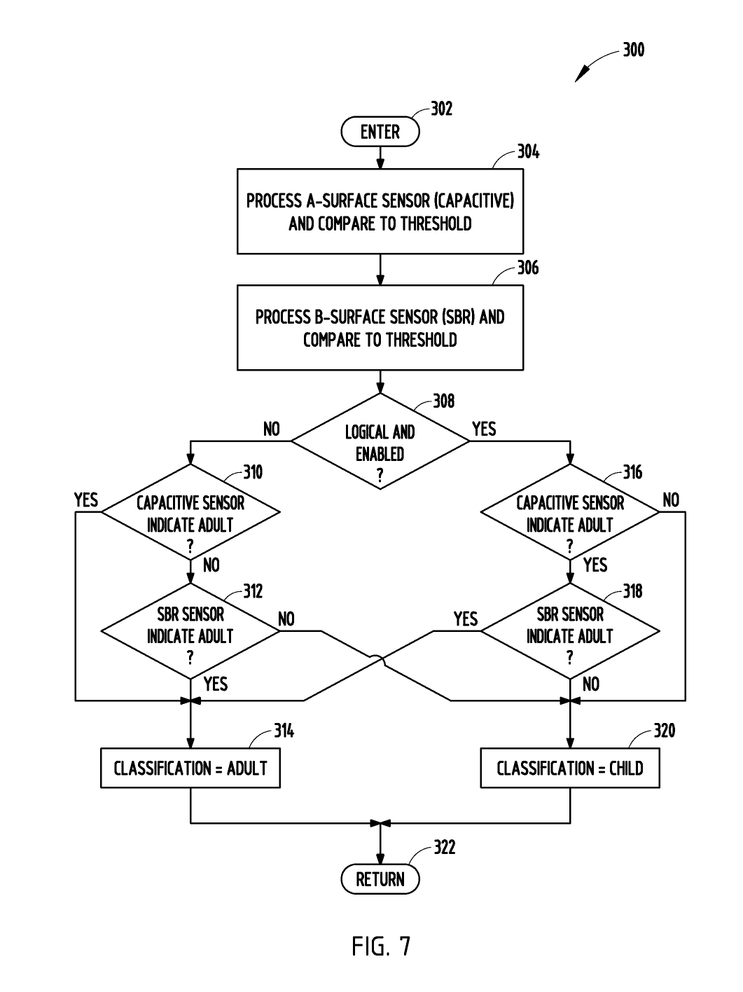

Referring to FIG. 7, an occupant detection routine 300 is illustrated for detecting an occupant based upon the capacitive sensor and force sensor outputs, according to one embodiment. Routine 300 begins at step 302 and proceeds to step 304 to process the A-surface sensor (capacitive) and compare the capacitive sensor output to a threshold value which is indicative of a characteristic of an occupant. The threshold value may be indicative of an adult occupant, as opposed to a child occupant. The processed capacitor signal may be acquired by routines 100 and 160 shown in FIGS. 4 and 5. Next, routine 300 proceeds to step 306 to process the B-surface sensor (force) (SBR) and to compare the force sensor output to a threshold force. The force threshold is indicative of a characteristic of an occupant, such as a weight of an occupant. According to one embodiment, the force threshold may be set to a predetermined weight, such as twenty-seven (27) pounds, according to one example. The force sensor output may be acquired by routine 200 shown in FIG. 6. Routine 300 then proceeds to decision step 308 to determine if the routine 300 is enabled in the logical “AND” mode. If the logical AND mode is enabled, routine 300 proceeds to decision step 316 to determine if the capacitive sensor output is indicative of an adult and, if not, proceeds to step 320 to classify the occupant as a child. If the capacitive sensor output is indicative of an adult, routine 300 proceeds to decision step 318 to determine if the SBR sensor is indicative of an adult and, if so, classifies the occupant as an adult in step 314. If neither the capacitive sensor nor SBR sensors outputs indicate an adult, routine 300 proceeds to step 320 to classify the occupant as a child, before returning at step 322.

Returning back to decision step 308, if the logical AND is not enabled, routine 300 uses a logical “OR” mode by proceeding to decision step 310 to determine if the capacitive sensor output is indicative of an adult and, if so, proceeds to classify the occupant as an adult in step 314 before returning at step 322. If the capacitive sensor output is not indicative of an adult, routine 300 proceeds to step 312 to determine if the SBR sensor output is indicative of an adult and, if so, classifies the occupant as an adult in step 314 before returning at step 322. If the SBR sensor output does not indicate an adult, routine 300 proceeds to classify the occupant as a child in step 320 before returning at step 322. Accordingly, routine 300 may require that both the capacitive sensor and the force sensor detect an adult occupant in a first mode in which the outputs are logically ANDed together, or may determine occupancy based on one or the other of the capacitive sensor and force sensor by logically ORing the outputs thereof.

Accordingly, the occupant detection system 20 and method advantageously detects the state of occupancy of a seat based on both a capacitive sensor output and force sensor output. By employing both the capacitive sensor output and force sensor output, the occupant detection system 20 may be configured to avoid situations of misclassification which may otherwise be present with the capacitive type sensor and force sensor when used individually. For example, if an electronic device, such as an inverter is plugged into an accessory port and is left on the seat or in proximity to the seat, the electronics may interfere with the capacitive sensor, and in such situation, the force output may avoid misclassification of occupancy. On the other hand, if a non-electronic device, such as a large container containing liquid is set upon the seat, the force sensor may be triggered, whereas the capacitive sensor may help avoid misclassification occupancy. While the capacitive sensor and force sensor outputs are shown according to one embodiment as being logically ANDed or logically ORed together according to one routine, it should be appreciated that other uses of the capacitive sensor output and force sensor output may be employed according to other embodiments.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. An occupant detection system comprising:
a capacitive sensor comprising an electrode arranged in a seat proximate to an expected location of an occupant for sensing an occupant presence proximate thereto, said capacitive sensor configured to provide an output indicative of the sensed occupant presence;
a force sensor arranged within the seat and providing an output indicative of a sensed force applied to the seat; and
occupant detection circuitry for processing the capacitive sensor output and the force sensor output and detecting a state of occupancy of the seat based on the capacitive sensor output and the force sensor output.

2. The occupant detection system as defined in claim 1, wherein the capacitive sensor output and force sensor output are logically ANDed to classify the occupant.

3. The occupant detection system as defined in claim 2, wherein the occupant detection circuitry classifies the occupant as one of an adult and a child.

4. The occupant detection system as defined in claim 1, wherein the capacitive sensor output and force sensor output are logically ORed to classify the occupant.

5. The occupant detection system as defined in claim 4, wherein the occupant detection circuitry classifies the occupant of one of a child and an adult.

6. The occupant detection system as defined in claim 1, wherein the occupant detection circuitry classifies the occupant of one of a child and an adult.

7. The occupant detection system as defined in claim 6, wherein the force sensor detects force indicative of one of a child and an adult.

8. The occupant detection system as defined in claim 1, wherein the force sensor comprises a seatbelt reminder sensor.

9. The occupant detection system as defined in claim 1, wherein the capacitive sensor comprises an electrically conductive mat disposed on the seat.

10. The occupant detection system as defined in claim 1, wherein the capacitive sensor comprises a signal generator for applying an alternating current signal to the electrode and a voltage detector for receiving a voltage signal, wherein the voltage signal is compared to a voltage threshold to generate the capacitive sensing output.

11. The occupant detection system as defined in claim 1, wherein the seat comprises a vehicle seat.

12. A method of detecting an occupant in a seat, said method comprising the steps of:
applying an alternating current signal to an electrode arranged in a seat proximate to an expected location of an occupant for generating an electric field at the expected location;
detecting a voltage response to the electric field;
generating a first output based on the voltage response indicative of a characteristic of an occupant;
sensing force applied to the seat by an occupant with the use of a force sensor located in the seat;
generating a second output indicative of the sensed force on the seat; and
processing the first output and the second output to detect a state of occupancy of the seat based on the first output and second output.

13. The method as defined in claim 12, wherein the first output and second output are logically ANDed to classify the occupant.

14. The method as defined in claim 12, wherein the first output and second output are logically ORed to classify the occupant.

15. The method as defined in claim 12, wherein the characteristic of an occupant is one of an adult and child.

16. The method as defined in claim 15, wherein the sensed force determines a force indicative of one of the adult and child.

17. The method as defined in claim 12, wherein the force sensor comprises a seatbelt reminder sensor.

18. The method as defined in claim 12, wherein the electrode provides capacitive sensing.

19. The method as defined in claim 12, wherein the seat is a vehicle seat.

20. The method as defined in claim 12, wherein the first output is generated based on a capacitive threshold.
